(19) United States
(12) Patent Application Publication
(10) Pub. No.: US 2025/0342875 A1
(43) Pub. Date: Nov. 6, 2025

(54) APPARATUSES AND METHODS TO REFRESH MEMORY INCLUDING MEMORY BANKS

(71) Applicant: MICRON TECHNOLOGY, INC., Boise, ID (US)

(72) Inventors: John Christopher M. Sancon, Boise, ID (US); Hyun Yoo Lee, Boise, ID (US)

(73) Assignee: MICRON TECHNOLOGY, INC., Boise, ID (US)

(21) Appl. No.: 19/187,790

(22) Filed: Apr. 23, 2025

Related U.S. Application Data
(60) Provisional application No. 63/641,086, filed on May 1, 2024.

(51) Int. Cl. G11C 11/406

(52) U.S. Cl. CPC G11C 11/40618

(57) ABSTRACT

Apparatuses and methods for a refresh operation performed on a memory bank from a subset of memory of memory bank groups in a high bank-count memory device. The memory banks may be divided into memory bank groups. The memory device may receive an external refresh command. The refresh command may indicate that a memory bank from each of the memory bank groups is to be refreshed (e.g., a same bank refresh operation) rather than refreshing all of the memory banks of all the memory groups (e.g., an all bank refresh operation). Responsive to the refresh command and a mode register setting further indicating that a smaller subset is to be refreshed (e.g., a same bank subset refresh operation), the refresh control circuit will refresh a memory bank from a subset of memory bank groups. As a result, the number of available memory banks during a refresh operation increases.

### CROSS-REFERENCE TO RELATED APPLICATIONS

This application claims the filing benefit of U.S. Provisional Application No. 63/641,086, filed May 1, 2024. This application is incorporated by reference herein in its entirety and for all purposes.

### BACKGROUND

Information may be stored on memory cells of a memory device. The memory cells may be organized at the intersection of word lines (rows) and bit lines (columns). The memory cells may be further organized into memory banks and memory bank groups. Information in the memory cells may decay over time. For example, the information may be stored as a charge on a capacitor which may decay over time. The memory device may perform refresh operations to restore the information and prevent information from being lost.

### BRIEF DESCRIPTION OF DRAWINGS

FIG. 1 is a block diagram of a semiconductor device according to at least one embodiment of the disclosure.

FIG. 2 is a block diagram of a refresh control circuit according to some embodiments of the present disclosure.

FIG. 3 is a block diagram of a memory array according to some embodiments of the present disclosure.

FIG. 4a is a block diagram of a refresh operation according to some embodiments of the present disclosure.

FIG. 4b is a block diagram of a refresh operation according to some embodiments of the present disclosure.

FIG. 4c is a block diagram of a refresh operation according to some embodiments of the present disclosure.

FIG. 4d is a block diagram of a refresh operation according to some embodiments of the present disclosure.

FIG. 4e is a block diagram of a refresh operation according to some embodiments of the present disclosure.

FIG. 5a is a diagram of time intervals for a sample refresh operation according to some embodiments of the present disclosure.

FIG. 5b is a diagram of time intervals for a sample refresh operation according to some embodiments of the present disclosure.

FIG. 5c is a diagram of time intervals for a sample refresh operation according to some embodiments of the present disclosure.

FIG. 6 is a table representing the relative timing of refresh operations according to some embodiments of the present disclosure.

FIG. 7 is a command table representing the commands for refresh operations according to some embodiments of the present disclosure.

FIG. 8 is a flow chart of a method of refreshing a memory array according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory devices store information in memory arrays. A memory array may include multiple memory banks. The memory banks may be grouped into bank groups. For example, a number of memory banks may be assigned to a bank group. A memory bank may contain multiple word lines. Information in a memory array may be accessed by one or more access operations, such as read or write operations. During an example access operation a word line may be activated based on a row address and then selected memory cells along that active word line may have their information read or written to, based on which bit lines are accessed. The bit lines that are accessed may be based on a column address.

The memory array may be refreshed on a row by row basis (e.g., as part of a refresh operation) where the memory cells along each row are refreshed periodically. The frequency at which the rows are refreshed (e.g., the maximum time any given row will go between refreshes) may be determined based on a refresh specification. During a refresh operation, the memory bank being refreshed is inaccessible for read or write operations. The number of refresh commands and the length of time a refresh operation lasts may depend on factors such as the type of refresh operation. For example, a refresh operation that is performed on all memory banks simultaneously will cause all memory banks of the array to be inaccessible for the duration of the refresh operation. Another refresh operation may be performed on only a subset of the memory banks at a time, such as refreshing one memory bank per bank group. During such a refresh operation, only the subset of banks will be inaccessible for the duration of the refresh operation and all other banks will be accessible. There may be a need to further reduce the number of banks that are inaccessible during a refresh operation.

The present disclosure is drawn to apparatuses, systems, and methods for refresh operations performed on memory banks in a memory device. For example, responsive to a first refresh command and/or a first refresh mode, a memory device may perform a refresh operation on all memory banks; responsive to a second refresh command and/or a second refresh mode, a memory device may perform a refresh operation on a memory bank in each bank group; and responsive to a third refresh command and/or a third refresh mode, a memory device may perform a refresh operation on a memory bank from less than all the bank groups. As a result, the number of available memory banks that are accessible during refresh operations increases. In some embodiments, a refresh mode may be set using a mode register setting.

In an example implementation, a memory device includes a refresh control circuit. The refresh control circuit receives a refresh command. The refresh command may indicate that a subset of the memory banks are to be refreshed (e.g., a same bank refresh operation) rather than all of the memory banks (e.g., an all bank refresh operation). Responsive to the refresh command and/or a mode register setting further indicating that a smaller subset is to be refreshed (e.g., a same bank subset refresh operation), the refresh control circuit will cause one or more memory banks from, for example, half of the memory bank groups to be subject to the refresh operation.

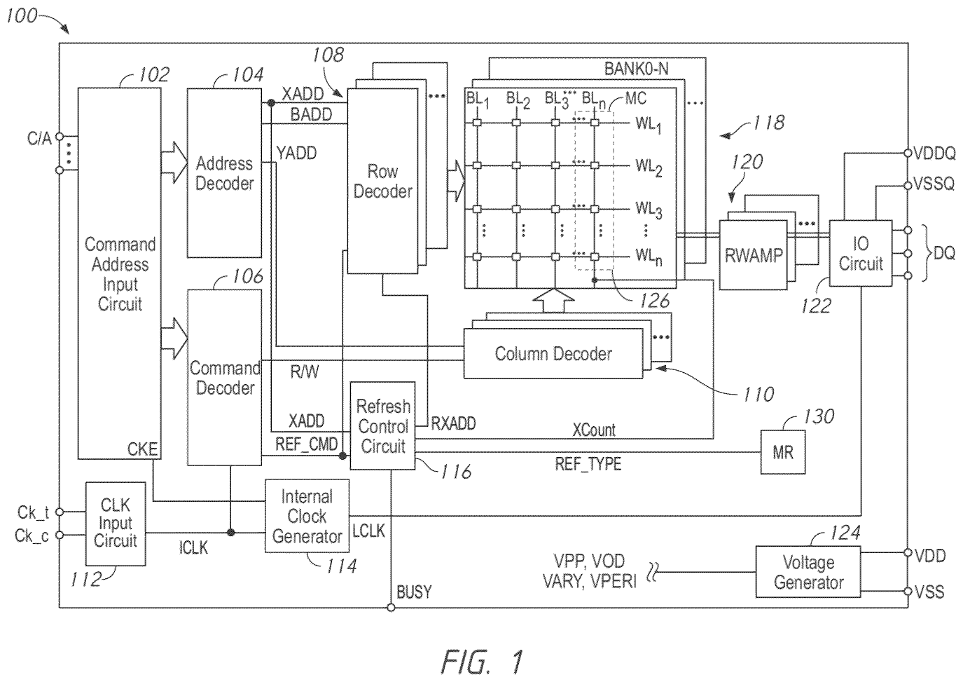

FIG. 1 is a block diagram of a semiconductor device according to at least one embodiment of the disclosure. The semiconductor device 100 may be a semiconductor memory device, such as a dynamic random access memory (DRA M) device integrated on a single semiconductor chip.

The semiconductor device 100 includes a memory array 118. The memory array 118 is shown as including a plurality of memory banks. In the embodiment of FIG. 1, the memory array 118 is shown as including memory banks BANK0-BANKN. The number of memory banks in the memory array 118 may, for example, be 4, 8, 16, or 32. More or fewer banks may be included in the memory array 118 of other embodiments. The memory banks may be further organized into memory bank groups (not shown in FIG. 1). For example, a device with thirty-two memory banks may be further organized into eight memory bank groups, with each bank group including four memory banks. Each memory bank includes a plurality of word lines WL (rows), a plurality of bit lines BL (columns), and a plurality of memory cells M C arranged at intersections of the plurality of word lines WL and the plurality of bit lines BL.

The selection of a word line WL is performed by a row decoder 108 and the selection of bit lines BL is performed by a column decoder 110. In the embodiment of FIG. 1, the row decoder 108 includes a respective row decoder for each memory bank and the column decoder 110 includes a respective column decoder for each memory bank.

Some of the memory cells may be set aside as counter memory cells 126. The counter memory cells may store count values X Count, each of which is associated with one of the word lines. Each count value X Count may be stored in counter memory cells 126 along the word line that the count value is associated with. The count value X Count may be stored as a binary number, with each bit stored in a memory cell along the word line. For the sake of clarity, a single bit line of counter memory cells 126 is shown in FIG. 1. However, the number of counter memory cells along each word line may be based on a number of bits of the count value X Count. In some embodiments, extra counter memory cells (e.g., more than the length of the number X Count) may be used, for example to store error correction information for the count value X Count.

The semiconductor device 100 may employ a plurality of external terminals that include command and address (C/A) terminals coupled to a command and address bus to receive commands and addresses, clock terminals to receive clocks Ck_t and Ck_c, data terminals DQ to provide data, and power supply terminals to receive power supply potentials VDD, VSS, VDDQ, and VSSQ.

The clock terminals are supplied with external clocks Ck_t and Ck_c that are provided to an input circuit 112. The external clocks may be complementary. The input circuit 112 generates an internal clock ICLK based on the Ck_t and Ck_c clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include access commands for accessing the memory, such as read commands for performing read operations and write commands for performing write operations, refresh command for performing refresh operations, mode register read and write commands for setting modes in a mode register, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and provide a column command signal to select a bit line.

The device 100 may receive an access command, such as a read command. When a read command is received, a bank address BADD and a column address YADD are timely supplied with the read command, read data is read from activated memory cells of row address XADD in the memory array 118 corresponding to the column address YADD. The read command is received by the command decoder 106, which provides internal commands so that read data from the memory array 118 is provided to the read/write amplifiers 120. The read data is output to outside from the data terminals DQ via the input/output circuit 122. The access count X Count stored counter memory cells 126 of the row associated with the row address XADD are read to the refresh address control circuit 116, and an updated value of the access count XCount′ (not shown) is written back to the counter memory cells 126 of the row XADD.

The device 100 may receive an access command, such as a write command. When the write command is received, a bank address BADD and a column address YADD are timely supplied with the write command, write data supplied to the data terminals DQ is written to activated memory cells of row address XADD in the memory array 118 corresponding to the column address YADD. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cells M C. Similar to the read operation described above, the access count X Count stored in counter memory cells 126 of the row associated with the row address XADD are read to the refresh address control circuit 116, and an updated value of the access count X Count′ is written back to the counter memory cells 126 of the row XADD.

The device 100 may also receive commands causing it to carry out refresh operations. For example, a controller of the memory may put the device 100 into an auto-refresh mode, which causes the command decoder 106 to provide an active refresh signal REF_CMD. The device 100 may also enter a self-refresh mode where the refresh signal is generated internally. Because other than the source of the refresh signal, the two operations may generally be similar, the present disclosure will generally describe auto-refresh operations (for example the refresh signal may be referred to as an ‘auto-refresh signal’). However, it should be understood that the present disclosure may apply to self-refresh (or other refresh modes) as well.

The refresh signal REF_CMD may be a pulse signal which is activated when the command decoder 106 receives a signal which indicates an auto-refresh command. In some embodiments, the auto-refresh command may be externally issued to the memory device 100. In some embodiments, the auto-refresh command may be periodically generated by a component of the device (e.g., as part of a self-refresh mode). In some embodiments, when an external signal indicates a self-refresh entry command, the refresh signal REF_CMD may also be activated. The refresh signal REF_CMD may be activated once immediately after command input, and thereafter may be cyclically activated at desired internal timing. Thus, refresh operations may continue automatically during self-refresh. A self-refresh exit command may cause the automatic activation of the refresh signal REF_CMD to stop and return to an IDLE state.

The refresh command REF_CMD is supplied to the refresh control circuit 116. The refresh control circuit 116 supplies a refresh row address RXADD to the row decoder 108, which refreshes a word line WL identified by the refresh row address RXADD. In some embodiments, the refresh control circuit 116 may also receive a mode register setting REF_TYPE.

The refresh control circuit 116 may selectively refresh a row from all of the memory banks or from a subset of the memory banks responsive to the refresh signal REF_CMD. The refresh control circuit 116 may selectively refresh a row from a specific subset of the memory banks (e.g., half of the memory banks) responsive to the mode register setting REF_TYPE. The mode register setting REF_TYPE may be programmed in the mode register 130, for example, by a mode register write operation.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

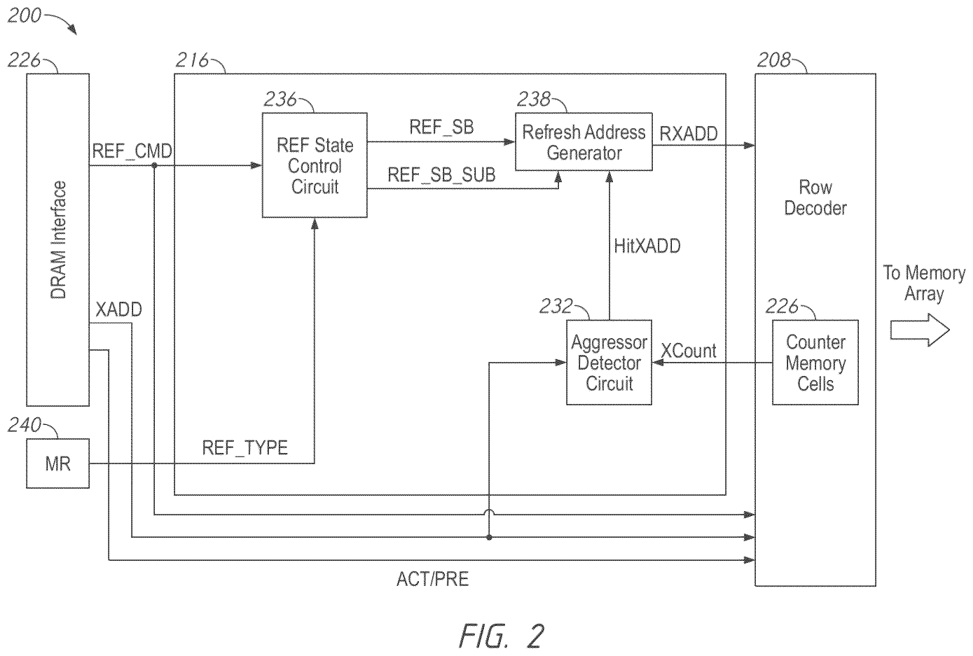

FIG. 2 is a block diagram of a refresh control circuit according to some embodiments of the present disclosure. The refresh control circuit 216 may, in some embodiments, be included in the refresh control circuit 116 of FIG. 1. Certain internal components and signals of the refresh control circuit 216 are shown to illustrate the operation of the refresh control circuit 216. The refresh control circuit 216 and row decoder 208 may correspond to a particular bank of memory, and one or more of these components may be repeated for each of the banks of memory. Some components may be shared in common by multiple bank level components. For example, there may be a refresh address generator 238 for each bank of memory, but the refresh state control circuit 236 may provide the refresh signal REF_AB, REF_SB, or REF_SB_SUB in common to each bank of memory.

A DRAM interface 226 may provide one or more signals to a refresh control circuit 216 and row decoder 208. The refresh control circuit 216 may include an aggressor detector circuit 232, a refresh (REF) state control circuit 236, and a refresh address generator 238. The DRAM interface 226 may provide one or more control signals, such as a refresh command signal REF_CMD, access signals such as an activation signal ACT and a pre-charge signal PRE, and a row address XADD. The refresh control circuit 216 provides refresh address RXADD based on the refresh signal REF_AB, REF_SB, or REF_SB_SUB

Responsive to a first type refresh command REF_CMD from the DRAM interface 226, the refresh state control circuit 236 may provide an all bank refresh signal REF_AB to indicate that an all bank refresh operation should occur. The refresh address generator 238 may provide a row address RXADD to the row decoder 208 to be refreshed in every memory bank of every memory bank group simultaneously. For example, if the memory array (e.g., 118 of FIG. 1) is divided into eight bank groups that each contain four memory banks, the row associated with row address RXADD will be refreshed in every memory bank in every memory bank group at the same time.

In another embodiment, the refresh state control circuit 236 may issue a same bank refresh signal REF_SB responsive to a second type of refresh command REF CM D in combination with a mode register signal REF_TYPE. For instance, the refresh state control circuit 236 may receive the second type of refresh command REF CM D indicating that a same bank refresh operation should be performed. The mode register signal REF_TYPE may also indicate that a same bank refresh operation should occur. The mode register signal REF_TYPE may be based on a setting in the mode register 240. For example, the mode register setting may be set responsive to an internal command or responsive to an external command, for instance, from a host such as a controller. Accordingly, the refresh state control circuit may issue a same bank refresh signal REF_SB to the refresh address generator 238 to provide the row addresses RXADD to the row decoder 208 for the same bank refresh operation. During the same bank refresh operation, the row associated with the row address RXADD is refreshed in a subset of the memory banks, rather than in all of the memory banks. For example, the row associated with row address RXADD may be refreshed in one memory bank of each memory bank group. If the memory array (e.g., 118 of FIG. 1) is divided into eight bank groups that each contain four memory banks, the row associated with row address RXADD will be refreshed in one memory bank in every memory bank group at the same time. Thus, eight memory banks will have the row associated with row address RXADD refreshed during the same bank refresh operation.

In another embodiment, the refresh state control circuit 236 may receive the second type refresh command REF_CMD indicating that a same bank refresh operation should be performed, and additionally, the mode register signal REF_TYPE may indicate that a same bank subset refresh operation should occur. In this case, the refresh state control circuit may issue a same bank subset refresh signal REF_SB_SUB to the refresh address generator 238 to provide a row address RXADD to the row decoder 208 for a same bank subset refresh operation. During the same bank subset refresh operation, the row associated with the row address RXADD is refreshed in a subset of the memory banks that is different than the subset of the memory banks refreshed by the same bank refresh operation. In some embodiments, the same bank subset refresh operation will refresh less memory banks in response to a refresh command than the same bank refresh operation. For example, for the same bank subset refresh operation, the row associated with row address RXADD may be refreshed in one memory bank of only half of the memory bank groups. If the memory array (e.g., 118 of FIG. 1) is divided into eight bank groups that each contain four memory banks, the row associated with row address RXADD will be refreshed in one memory bank in half of the memory bank groups at the same time, thus only four memory banks will have the row associated with row address RXADD refreshed during the same bank subset refresh operation.

The DRAM interface 226 may represent one or more components which provides signals to components of the bank. In some embodiments, the DRA M interface 226 may represent a memory controller coupled to the semiconductor memory device (e.g., device 100 of FIG. 1). In some embodiments, the DRA M interface 226 may represent components such as the command address input circuit 102, the address decoder 104, and/or the command decoder 106 of FIG. 1. The DRAM interface 226 may provide a row address XADD, a bank address BADD, the refresh command REF_CMD, and access signals such as an activation signal ACT and a pre-charge signal PRE. The refresh command REF_CMD may be a signal that indicates when a refresh operation is to occur. The access signals ACT and PRE may generally be provided as part of an access operation along with a row address XADD. The activation signal ACT may be provided to activate a bank and row of the memory associated with the associated bank and row address. The pre-charge signal PRE may be provided to pre-charge the bank and row of the memory specified by the bank and row address. The row address XADD may be a signal including multiple bits (which may be transmitted in series or in parallel) and may correspond to a specific row of an activated memory bank.

A mode register 240 may provide signals to the refresh state control circuit 236. The mode register 240 may, in some embodiments, be an implementation of the mode register 130 of FIG. 1. The mode register 240 may provide a mode register signal REF TY PE to the refresh state control circuit 236, which represents a mode register setting that specifies a type of refresh operation, such as a same bank refresh operation or a same bank subset refresh operation. For example, the value REF_TYPE may be set based on user inputs specifying the desired type of refresh operation (e.g., same bank refresh). In some examples, the value REF_TYPE may be set based on a command from a host such as a controller. In some embodiments, the mode register signal REF_TYPE may be used in combination with the refresh command REF_CMD by the refresh state control circuit 236 to determine which type of refresh operation to perform.

The aggressor detector circuit 232 may determine aggressor addresses based on one or more of the sampled row and bank addresses, and then may provide the determined aggressor address as the match address HitX ADD. The aggressor detector circuit 232 may include a data storage unit (e.g., a number of registers), which may be used to store sampled row and bank addresses. When the aggressor detector circuit 232 samples a new value of the row address X ADD, it may compare the sampled row and bank address to the row/bank addresses stored in the data storage unit. In some embodiments, the match address HitX ADD may be one of the addresses stored in the aggressor detector circuit 232 which has been matched by the sampled addresses the most frequently. The refresh address generator 238 may also provide a refresh address RXADD, which may be one or more victim addresses corresponding to victim rows of the aggressor row corresponding to the match address HitX ADD provided by the aggressor detector circuit 232. The aggressor detector circuit 232 may include a queue of identified aggressor addresses, and provide an address HitX ADD when a targeted refresh operation is called for.

In some embodiments, the refresh control circuit 216 may perform multiple refresh operations responsive to each activation of the refresh command REF_CMD. For example, each time the refresh command REF_CMD is received, the refresh control circuit 216 may perform N different refresh operations, by providing N different refresh addresses RXADD. Each refresh operation may be referred to as a ‘pump’.

The row decoder 208 may perform one or more operations on the memory array (not shown in FIG. 2) based on the received signals and addresses. For example, responsive to the activation signal ACT and the row address XADD, the row decoder 208 may direct one or more access operations (for example, a read operation) on the specified row address XADD. In some embodiments, responsive to the refresh command REF_CMD being active, the row decoder 208 may refresh the refresh address RXADD.

The refresh address generator 238 may generate a refresh address RXADD based on the refresh signal from the refresh state control circuit 236 (e.g., REF_AB, REF_SB, REF_SB_SUB). The refresh address generator 238 may use logic circuits to cycle through addresses for all of the word lines in the memory array. For example, the refresh address generator 238 may include a counter which increments a value of RXADD each time a row corresponding to a previous RXADD is refreshed.

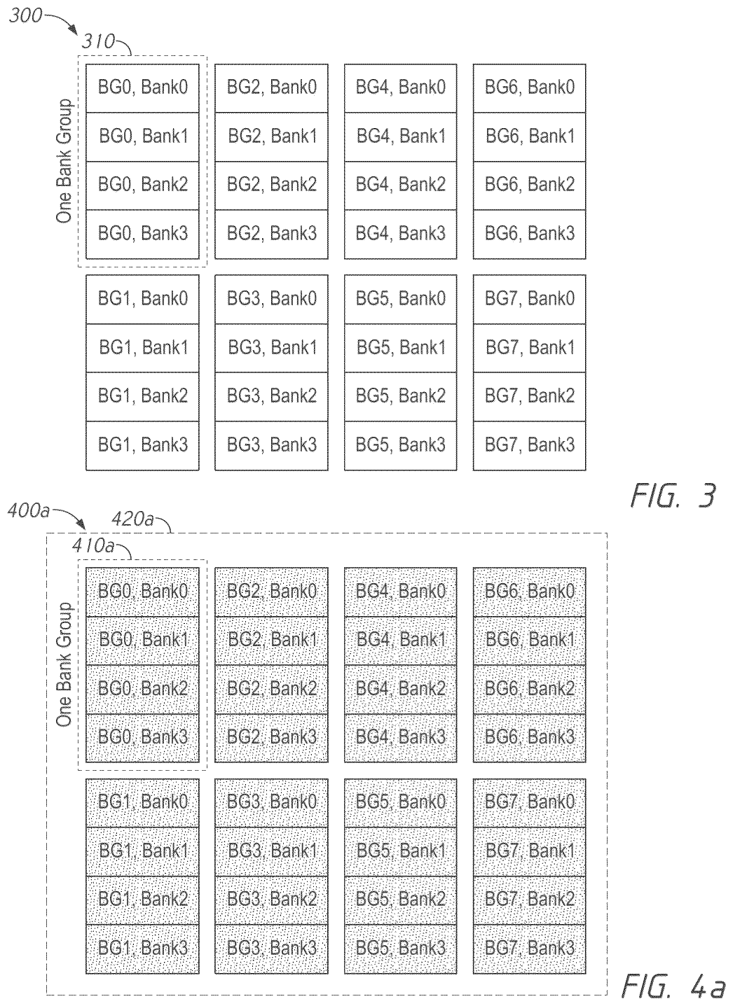

FIG. 3 is a block diagram of a memory array according to some embodiments of the present disclosure. In some embodiments, memory array 300 may be an implementation of memory array 118 of FIG. 1. For example, the memory banks of FIG. 3 may be an implementation of the memory banks BANK0-BANKN of FIG. 1. The memory array 300 is shown with thirty-two memory banks. M ore or fewer banks may be included in the memory array 300 of other embodiments.

In some embodiments, the memory banks of memory array 300 may be grouped into bank groups. For example, the 32 memory banks of memory array 300 are grouped into eight bank groups BG0-BG7, with each bank group including four banks Bank0-Bank3. In FIG. 3, each bank group may be identified by a bank group index, such as bank group index 0-7, and additionally each memory bank of a bank group may be identified by a memory bank index, such as memory bank index 0-3. Bank group 310 may be referenced as BG0. Different grouping schemes of more or fewer banks may be combined into more or fewer bank groups in other embodiments.

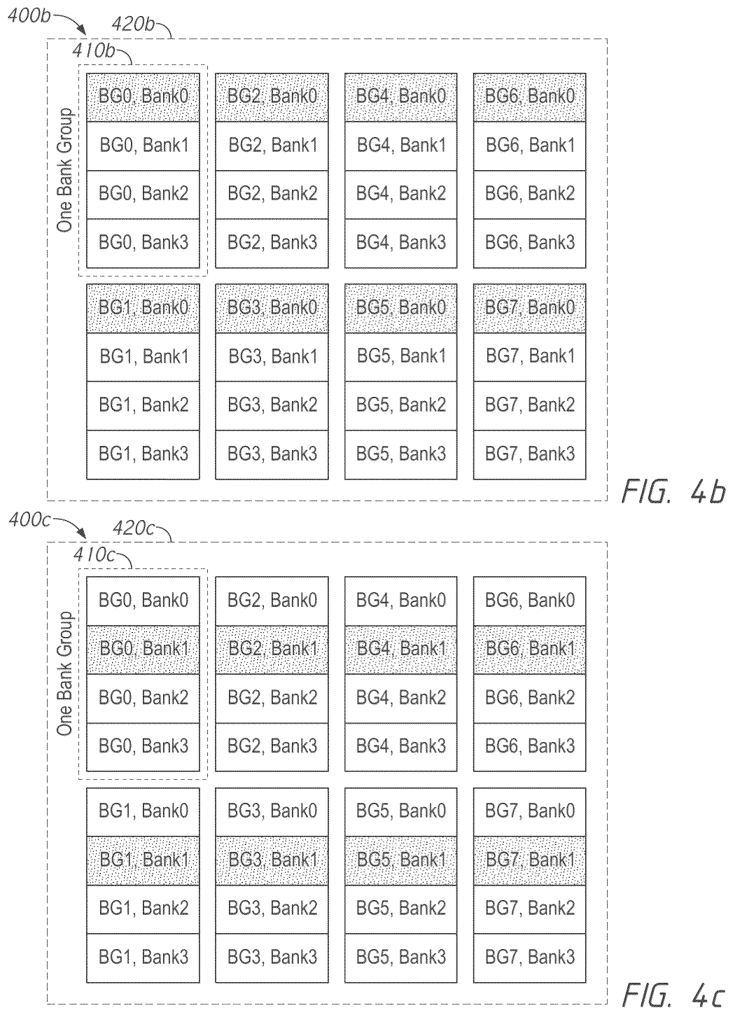

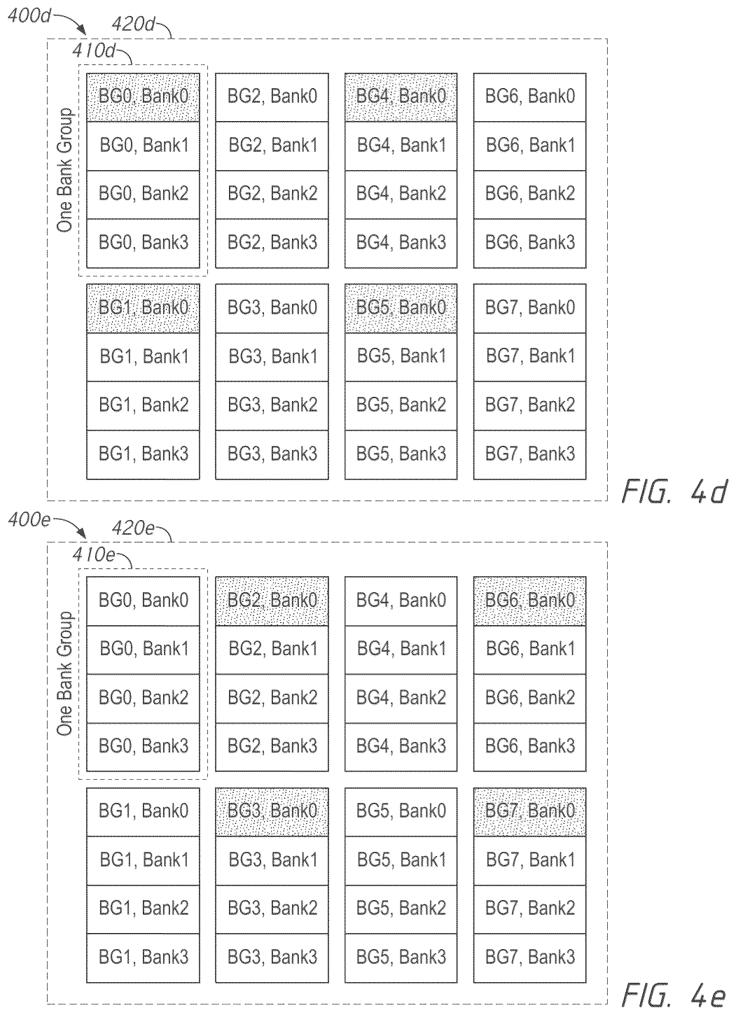

FIG. 4a is a block diagram of a refresh operation according to some embodiments of the present disclosure. Memory array 420a may be an implementation of memory array 300 of FIG. 3 and/or memory array 118 of FIG. 1. Bank group 410a may be an implementation of bank group 310 of FIG. 3 and memory banks BG0, Bank0-BG7, Bank 3 may be an implementation of memory banks BG0, Bank0-BG7, Bank 3 of FIG. 3 and/or the memory banks BANK0-BANKN of FIG. 1. The memory banks BG0, Bank0-BG7, Bank 3 of memory array 420a may be divided into eight bank groups BG0-BG7, each consisting of four memory banks. Different grouping schemes of more or fewer banks may be combined into more or fewer bank groups in other embodiments.

In some embodiments, the refresh operation 400a may be an implementation of an all bank refresh operation (e.g., performed responsive to the refresh signal REF_AB of FIG. 2). During the refresh operation 400a, a row, such as a row associated with a row address RXADD of FIG. 2, may be refreshed in all memory banks BG0, Bank0-BG7, Bank3 of all bank groups BG0-BG7 may be refreshed simultaneously, as indicated in FIG. 4a by all memory banks being shaded.

FIG. 4b is a block diagram of a refresh operation according to some embodiments of the present disclosure. Memory array 420b may be an implementation of memory array 300 of FIG. 3 and/or memory array 118 of FIG. 1. Bank group 410b may be an implementation of bank group 310 of FIG. 3 and memory banks BG0, Bank0-BG7, Bank 3 may be an implementation of memory banks BG0, Bank0-BG7, Bank 3 of FIG. 3 and/or the memory banks BANK 0-BANKN of FIG. 1. The memory banks BG0, Bank0-BG7, Bank 3 of memory array 420b may be divided into eight bank groups BG0-BG7, each consisting of four memory banks. Different grouping schemes of more or fewer banks may be combined into more or fewer bank groups in other embodiments.

In some embodiments, the refresh operation 400b may be an implementation of a same bank refresh operation (e.g., performed responsive to the refresh signal REF_SB of FIG. 2). During refresh operation 400b, a row, such as a row associated with a row address RXADD of FIG. 2, may be refreshed in less than all memory banks BG0, Bank0-BG7, Bank3 at one time. For example, the row associated with row address RXADD in eight memory banks (e.g., one memory bank from each bank group) may be refreshed simultaneously. In some examples, the memory bank index may be the same in each bank group (e.g., Bank0 from each bank group BG0-BG7), as indicated in FIG. 4b by a same bank (Bank 0) in each bank group BG0-BG7 being shaded.

FIG. 4c is a block diagram of a refresh operation according to some embodiments of the present disclosure. Memory array 420c may be an implementation of memory array 300 of FIG. 3 and/or memory array 118 of FIG. 1. Bank group 410c may be an implementation of bank group 310 of FIG. 3 and memory banks BG0, Bank0-BG7, Bank 3 may be an implementation of memory banks BG0, Bank0-BG7, Bank 3 of FIG. 3 and/or the memory banks BANK 0-BANKN of FIG. 1. The memory banks BG0, Bank0-BG7, Bank 3 of memory array 420c may be divided into eight bank groups BG0-BG7, each consisting of four contiguous memory banks. Different grouping schemes of more or fewer banks may be combined into more or fewer bank groups in other embodiments.

In some embodiments, the refresh operation 400c may be an implementation of a same bank refresh operation (e.g., performed responsive to a subsequent refresh signal REF_SB of FIG. 2) subsequent to the same bank refresh operation 400b of FIG. 4b. During the subsequent refresh operation 400c, the row associated with a row address RXADD in a next set of less than all memory banks BG0, Bank0-BG7, Bank3 may be refreshed at one time. For example, the row associated with the row address RXADD in the next set of eight memory banks (e.g., a next one memory bank from each bank group) may be refreshed simultaneously. In some examples, the next memory bank index may be the same in each bank group (e.g., Bank1 from each bank group BG0-BG7), as indicated in FIG. 4c by a same bank (Bank 1) in each bank group BG0-BG7 being shaded.

FIG. 4d is a block diagram of a refresh operation according to some embodiments of the present disclosure. Memory array 420d may be an implementation of memory array 300 of FIG. 3 and/or memory array 118 of FIG. 1. Bank group 410d may be an implementation of bank group 310 of FIG. 3 and memory banks BG0, Bank0-BG7, Bank 3 may be an implementation of memory banks BG0, Bank0-BG7, Bank 3 of FIG. 3 and/or the memory banks BANK 0-BANKN of FIG. 1. The memory banks BG0, Bank0-BG7, Bank 3 of memory array 420d may be divided into eight bank groups BG0-BG7, each consisting of four memory banks. Different grouping schemes of more or fewer banks may be combined into more or fewer bank groups in other embodiments.

In some embodiments, the refresh operation 400d may be an implementation of a same bank subset refresh operation (e.g., performed responsive to the refresh signal REF_SB_SUB of FIG. 2). During refresh operation 400d, a row associated with row address RXADD may be refreshed in memory banks from less than all bank groups BG0-BG7 at one time. For example, the row associated with row address RXADD may be refreshed in four memory banks (e.g., one memory bank from half of the total number of bank groups) simultaneously. In some examples, the memory bank index may be the same across the bank group division and the bank group division may be based on the bank group index (e.g., Bank0 from each bank group BG0, BG1, BG4, BG5), as indicated in FIG. 4d by a same bank (Bank 0) in each bank group BG0, BG1, BG4, BG5 being shaded.

FIG. 4e is a block diagram of a refresh operation according to some embodiments of the present disclosure. Memory array 420e may be an implementation of memory array 300 of FIG. 3 and/or memory array 118 of FIG. 1. Bank group 410d may be an implementation of bank group 310 of FIG. 3 and memory banks BG0, Bank0-BG7, Bank 3 may be an implementation of memory banks BG0, Bank0-BG7, Bank 3 of FIG. 3 and/or the memory banks BANK 0-BANKN of FIG. 1. The memory banks BG0, Bank0-BG7, Bank 3 of memory array 420e may be divided into eight bank groups BG0-BG7, each consisting of four memory banks. Different grouping schemes of more or fewer banks may be combined into more or fewer bank groups in other embodiments.

In some embodiments, the refresh operation 400e may be an implementation of a same bank subset refresh operation (e.g., performed responsive to a subsequent refresh signal REF_SB_SUB of FIG. 2) subsequent to the same bank subset refresh operation 400d of FIG. 4d. During the subsequent refresh operation 400e, a row associated with row address RXADD may be refreshed in memory banks from a next set of less than all bank groups BG0-BG7 at one time. For example, the row associated with row address RXADD may be refreshed in another four memory banks (e.g., one memory bank from the other half of the total number of bank groups) simultaneously. In some examples, the memory bank index may be the same as in the previous same bank subset refresh operation. In some examples, the memory bank index may be the same across the bank group division and the bank group division may be based on the bank group index (e.g., Bank0 from each bank group BG2, BG3, BG6, BG7), as indicated in FIG. 4e by a same bank (Bank 0) in each bank group BG2, BG3, BG6, BG7 being shaded.

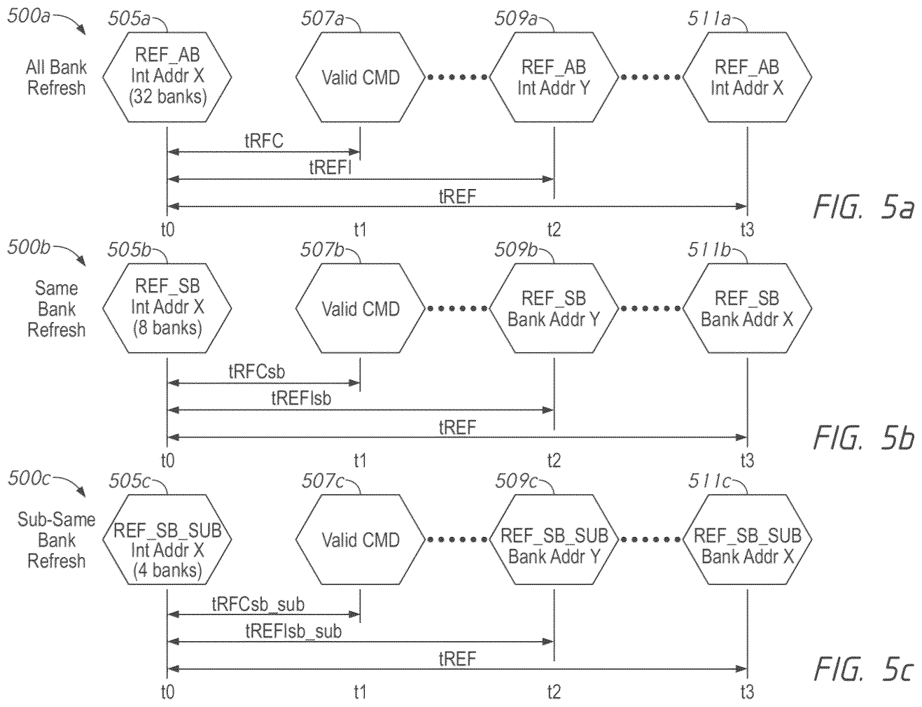

FIG. 5a is a diagram of time intervals for a sample refresh operation according to some embodiments of the present disclosure. The timing diagram 500a may, in some embodiments, represent the timing of a refresh operation performed by semiconductor device 100. In the example embodiment, the timing diagram 500a shows an all bank refresh operation (e.g., 400a of FIG. 4a) responsive to an external all bank refresh command 505a received by semiconductor device 100. It should be appreciated that the timing intervals of FIG. 5a are not drawn to scale.

At an initial time to, in some embodiments, all bank refresh command 505a is received, for instance by a command address input circuit 102 of FIG. 1. Responsive to the all bank refresh command 505a, the refresh control circuit (e.g., 216 of FIG. 2) may issue a refresh signal (e.g., REF_AB of FIG. 2) to initiate an all bank refresh operation.

Between the initial time t0 and a first time t1, beginning with an initial refresh address Int A ddr X, such as row address RXADD of FIG. 2, the refresh control circuit will refresh a row from memory banks according to the refresh operations. For example, during an all bank refresh operation, the same row from each memory bank (e.g., BG0, Bank0-BG7, Bank 3 of FIGS. 3-4) in the memory array (e.g., 118 of FIG. 1, 300 of FIGS. 3, and/or 400a-e of FIGS. 4a-e) will be refreshed simultaneously. While the rows are being refreshed, the memory banks in which those rows are located are inaccessible. Some standards call this time period time for refresh completion tRFC. In the example embodiment, refresh operations are completed for one or more rows in each memory bank of the memory array within the time for refresh completion tRFC (e.g., t0 to t1). At time t1, the memory banks subject to the refresh operation will again be accessible, and a valid command 507a may be accepted by the memory to perform an operation in those memory banks.

The time between the initial time to and a second time t2 is an average time between the issuance of refresh commands. Some standards may call this a refresh interval tREFI. The refresh interval tREFI may be an average time between refresh commands that need to be issued to refresh the entire memory array in a predetermined amount of time, such as a refresh period, as will be described in greater detail below. As shown in FIG. 5a, a next all bank refresh command 509a may be received by the memory tREFI after the all bank refresh command 505a. A next refresh address Int A ddr Y is refreshed by the all bank refresh command 509a. The refresh interval tREFI may depend on factors such as temperature and the type of refresh operation. Between the first time t1 and the second time t2, the memory banks may be accessible.

The time between the initial time to and a third time t3 is a total amount of time to refresh the entire memory array. Some standards may call this time a refresh period tREF. For example, a refresh period tREF of 32 ms means that the entire memory array should be refreshed over 32 ms, or put another way, each row in the memory array must be refreshed every 32 ms. As shown in FIG. 5a, a refresh command 511a received by the memory at time t3 is directed to the initial refresh address Int A ddr X, that was previously refreshed in response to all bank the refresh command 505a at time to. The refresh period tREF may in some embodiments represent the amount of time to complete refresh operations for an entire memory array to prevent data loss.

FIG. 5b is a diagram of time intervals for a sample refresh operation according to some embodiments of the present disclosure. The timing diagram 500b may, in some embodiments, represent the timing of a refresh operation performed by semiconductor device 100. In the example embodiment, the timing diagram 500b shows same bank refresh operation (e.g., 400b and 400c of FIGS. 4b-c) responsive to an external same bank refresh command 505b received by semiconductor device 100. It should be appreciated that the timing intervals of FIG. 5b are not drawn to scale.

At an initial time t0, in some embodiments, refresh command 505b is received, for instance by a command address input circuit 102 of FIG. 1. Responsive to the same bank refresh command 505b, the refresh control circuit (e.g., 216 of FIG. 2) may issue a refresh signal (e.g., REF_SB of FIG. 2) to initiate a same bank refresh operation.

Between the initial time t0 and a first time t1, beginning with a bank address Bank A ddr X, the refresh control circuit will refresh a row from memory banks according to the refresh operations. For example, during a same bank refresh operation, the same row from one memory bank (e.g., BG0, Bank0-BG7, Bank 0 of FIGS. 3-4) from each bank group (e.g., BG0-BG7 of FIGS. 3-4) in the memory array (e.g., 118 of FIG. 1, 300 of FIGS. 3, and/or 400a-e of FIGS. 4a-e) will be refreshed simultaneously. While the rows are being refreshed, the memory banks in which those rows are located are inaccessible. This time period may be called time for same bank refresh completion tRFCsb. In the example embodiment, refresh operations are completed for one or more rows in a subset of memory banks of the memory array within the time for same bank refresh completion tRFCsb (e.g., t0 to t1). At time t1, the memory banks subject to the refresh operation will again be accessible, and a valid command 507b may be accepted by the memory to perform an operation in those memory banks.

The time between the initial time to and a second time t2 is an average time between the issuance of refresh commands. This time period may be called a same bank refresh interval tREFIsb. The same bank refresh interval tREFIsb may be an average time between refresh commands that need to be issued to refresh the entire memory array in a predetermined amount of time, such as a refresh period, as will be described in greater detail below. As shown in FIG. 5b, a next same bank refresh command 509b is issued tREFIsb after the same bank refresh command 505b. One or more rows of a next bank address Bank A ddr Y are refreshed by the same bank refresh command 509b. The same bank refresh interval tREFIsb may depend on factors such as temperature and the type of refresh operation. Between the first time t1 and the second time t2, the memory banks may be accessible.

The time between the initial time to and a third time t3 is a total amount of time to refresh the entire memory array. Some standards may call this time a refresh period tREF. For example, a refresh period tREF of 32 ms means that the entire memory array should be refreshed over 32 ms, or put another way, each row in the memory array must be refreshed every 32 ms. As shown in FIG. 5b, a refresh command 511b at time t3 is directed to the initial bank address Bank Addr X that was previously refreshed in response to the refresh command 505b at time t0. The refresh period tREF may in some embodiments represent the amount of time to complete refresh operations for an entire memory array to prevent data loss.

FIG. 5c is a diagram of time intervals for a sample refresh operation according to some embodiments of the present disclosure. The timing diagram 500c may, in some embodiments, represent the timing of a refresh operation performed by semiconductor device 100. In the example embodiment, the timing diagram 500c shows same bank subset refresh operation (e.g., 400b and 400c of FIGS. 4b-c) responsive to an external same bank subset refresh command 505c received by semiconductor device 100. It should be appreciated that the timing intervals of FIG. 5c are not drawn to scale.

At an initial time t0, in some embodiments, same bank subset refresh command 505c is received, for instance by a command address input circuit 102 of FIG. 1. Responsive to the same bank subset refresh command 505c, the refresh control circuit (e.g., 216 of FIG. 2) may issue a refresh signal (e.g., REF_SB_SUB of FIG. 2) to initiate a same bank subset refresh operation.

Between the initial time t0 and a first time t1, beginning with an initial bank address Bank A ddr X, the refresh control circuit will refresh a row from memory banks according to the refresh operations. For example, during a same bank subset refresh operation, the same row from one memory bank (e.g., BG0, Bank0; BG2, Bank0; BG4, Bank 0; BG6, Bank 0 of FIGS. 3-4) from a subset of the bank groups (e.g., BG0, BG2, BG4, BG6 of FIGS. 3-4) in the memory array (e.g., 118 of FIG. 1, 300 of FIGS. 3, and/or 400a-e of FIGS. 4a-e) will be refreshed simultaneously. While the rows are being refreshed, the memory banks in which those rows are located are inaccessible. This time period may be called time for same bank subset refresh completion tRFCsb_sub. In the example embodiment, refresh operations are completed for one or more rows in a subset of the memory banks and a subset of memory bank groups of the memory array within the time for same bank subset refresh completion tRFCsb_sub (e.g., t0 to t1). At time t1, the memory banks subject to the refresh operation will again be accessible, and a valid command 507c may be accepted by the memory to perform an operation in those memory banks.

The time between the initial time to and a second time t2 is an average time between the issuance of refresh commands. This time period may be called a same bank subset refresh interval tREFIsb_sub. The same bank subset refresh interval tREFIsb_sub may be an average time between refresh commands that need to be issued to refresh the entire memory array in a predetermined amount of time, such as a refresh period, as will be described in greater detail below. As shown in FIG. 5c, a same bank subset refresh command 509c is issued tREFIsb_sub after the same bank subset refresh command 505c. A next bank address Bank A ddr Y is refreshed by the same bank subset refresh command 509c. The same bank subset refresh interval tREFIsb_sub may depend on factors such as temperature and the type of refresh operation. Between the first time t1 and the second time t2, the memory banks may be accessible.

The time between the initial time to and a third time t3 is a total amount of time to refresh the entire memory array. Some standards may call this time a refresh period tREF. For example, a refresh period tREF of 32 ms means that the entire memory array should be refreshed over 32 ms, or put another way, each row in the memory array must be refreshed every 32 ms. As shown in FIG. 5c, a refresh command 511c at time t3 is directed to the initial bank address Bank A ddr X that was previously refreshed in response to the refresh command 505c at time t0. The refresh period tREF may in some embodiments represent the amount of time to complete refresh operations for an entire memory array to prevent data loss.

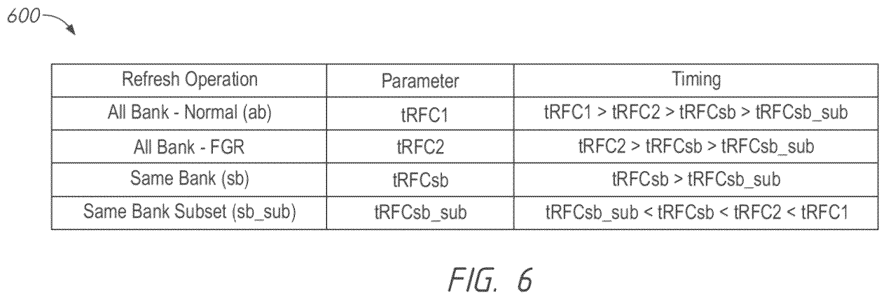

FIG. 6 is a table representing the relative timing of refresh operations according to some embodiments of the present disclosure. Table 600 may represent the timing parameters of different refresh operation relative to one another, for example. The timing parameters may represent the timing parameters tRFC, tRFCsb, tRFCsb_sub of FIGS. 5a-c. The refresh operations may be the refresh operations 400a-400e of FIGS. 4a-e and/or the refresh operations 500a-500c of FIGS. 5a-c.

Some of the timing parameters (e.g., tRFC, tRFCsb, tRFCsb_sub) of the different refresh operations (e.g., all bank, same bank, same bank subset) may be different relative to one another. For example, the time for refresh completion tRFC for an all bank refresh operation (e.g., tRFC of FIG. 5a) in what some standards may call “normal” mode may be longer than the time for refresh completion tRFC2 (not shown in the figures) for an all bank refresh operation in what some standards may call “fine granularity refresh (FGR)” mode. In some embodiments, the time for refresh completion tRFC2 of an FGR all bank refresh operation may be longer than the time for same bank refresh completion tRFCsb (e.g., tRFCsb of FIG. 5b). In some embodiments, the time for same bank refresh completion tRFCsb (e.g., tRFCsb of FIG. 5b) may be longer than the time for same bank subset refresh completion tRFCsb_sub (e.g., tRFCsb_sub of FIG. 5c).

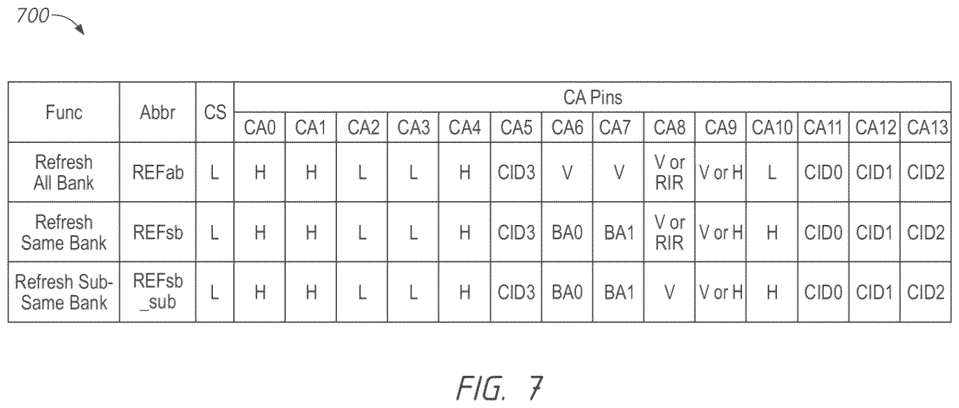

FIG. 7 is a command table representing the commands for refresh operations according to some embodiments of the present disclosure. For example, table 700 may represent external commands issued to a semiconductor device, such as semiconductor device 100, to perform refresh operations.

In some embodiments, each command represented by table 700 may represent a different refresh operation (e.g., REFab, REFsb, REFsb_sub). For example, responsive to a REFab command, an all bank refresh operation is performed; responsive to a REFsb command, a same bank refresh operation is performed; and responsive to a REFsb_sub command, a same bank subset refresh operation is performed.

In the table of FIG. 7, “L” indicates a low logic state and “H” indicates a high logic state for the corresponding command terminal CA, “CIDn” indicates an nth bit of chip identification information, “BAm” indicates an mth bit of a bank address, “V” indicates a valid logic state, and “RIR” indicates a refresh interval rate.

In some embodiments, the commands represented by table 700 may be read in conjunction with a mode register setting (e.g., REF_TYPE of FIGS. 1-2) to perform a refresh operation. For example, a same bank refresh command and a same bank subset refresh command may have the same command code, as shown in the table of FIG. 7. However, a same bank refresh operation is performed in response to the refresh command code when the mode register setting REF_TYPE has a first value, and a same bank subset refresh operation is performed in response to the same refresh command code when the mode register setting REF_TYPE has a second value.

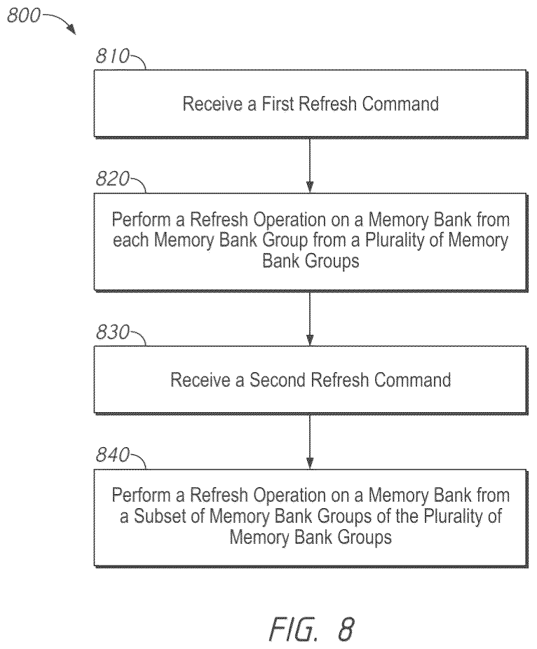

FIG. 8 is a flow chart of a method of refreshing a memory array according to some embodiments of the present disclosure. The method 800 may, in some embodiments, be implemented by one or more of the systems or apparatuses described herein. For example, the method may be performed by the semiconductor device 100 of FIG. 1.

At block 810, the method 800 may include receiving a first refresh command. The first refresh command may be an external refresh command issued by a memory controller to a semiconductor device to perform a refresh operation.

At block 820, the method 800 may include performing a refresh operation on a first subset of memory banks responsive to the first refresh command, where the first subset of memory banks includes a first corresponding one of the memory banks from each memory bank group of a plurality of memory bank groups. In some embodiments, the first subset of memory banks may be an implementation of memory banks BG0, Bank0-BG7, Bank0 of FIG. 4b (e.g., a same bank refresh operation). For example, a row in eight memory banks (e.g., one memory bank from each bank group) may be refreshed simultaneously. In some examples, the memory bank index may be the same in each memory bank group (e.g., Bank0 from each memory bank group BG0-BG7 of FIG. 4b).

At block 830, the method 800 may include receiving a second refresh command. The second refresh command may be an external refresh command issued by the memory controller to the semiconductor device to perform a refresh operation.

At block 840, the method 800 may include performing a refresh operation on a second subset of memory banks responsive to the second refresh command, where the second subset of memory banks includes a second corresponding one of the memory banks from the plurality of memory bank groups. In some embodiments, the second subset of memory banks may be an implementation of memory banks BG0, Bank0; BG1, Bank0; BG4, Bank0; BG5, Bank0 of FIG. 4d (e.g., a same bank subset refresh operation). For example, the row in four memory banks (e.g., one memory bank from half of the eight memory bank groups) may be refreshed simultaneously. In some examples, the memory bank index may be the same in each bank group (e.g., Bank0 from each even memory bank group BG0, BG1, BG4, BG5 of FIG. 4d).

In some embodiments, the method 800 may include receiving a third refresh command. The third refresh command may be an external refresh command issued by the memory controller to the semiconductor device to perform a refresh operation.

Responsive to the third refresh command, the method 800 may include performing a refresh operation on all of the memory banks of all of the memory bank groups. In some embodiments, the refresh operation performed in response to the third refresh command may be an implementation of the refresh operation show in FIG. 4a (e.g., an all bank refresh operation).

In some embodiments, the method 800 may further include setting a mode register. The mode register may be an implementation of the mode register 130 of FIGS. 1 and/or 240 of FIG. 2. In some embodiments, the mode register setting may be an implementation of mode register signal REF_TYPE of FIGS. 1-2.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array comprising a plurality of memory bank groups each comprising a plurality of memory banks; and
a refresh control circuit configured to perform a refresh operation on a memory bank from a subset of the memory bank groups of the plurality of memory bank groups responsive to a first type of refresh command.

2. The apparatus of claim 1, wherein the refresh control circuit is further configured to perform the refresh operation on a memory bank from each of the memory groups of the plurality of memory groups responsive to a second type of command of the first type of refresh command.

3. The apparatus of claim 1, wherein the subset of memory bank groups of the plurality of memory bank groups comprises half of the plurality of memory bank groups.

4. The apparatus of claim 1, wherein the refresh control circuit is further configured to perform the refresh operation on all of the memory banks of the plurality of memory banks responsive to a third type of refresh command.

5. The apparatus of claim 1, wherein the first type of refresh command is based on a command code and a first mode register setting and the second type of refresh command is based on the command code and a second mode register setting.

6. The apparatus of claim 5, wherein the mode register setting is set by a host.

7. The apparatus of claim 1, wherein an amount of time to perform the refresh operation responsive to the first type of refresh command is longer than the amount of time to perform the refresh operation responsive to the second type of refresh command.

8. An apparatus comprising:
a memory array comprising a plurality of memory bank groups each comprising a plurality of memory banks;
a refresh state control circuit configured to issue a first, second, and third type of refresh signal; and
a refresh address generator configured to generate a row address to be refreshed in a set of memory banks, wherein the set of memory banks is all of the memory banks in all of the memory bank groups of the plurality of memory bank groups responsive to the first refresh signal, the set of memory banks is a memory bank from each memory bank group of the plurality of memory bank groups responsive to the second refresh signal, and the set of memory banks is a memory bank from a subset of memory bank groups of the plurality of memory bank groups responsive to the third refresh signal.

9. The apparatus of claim 8, wherein the first refresh signal is based on a first refresh command and the second refresh signal and the third refresh signal are based on a second refresh command.

10. The apparatus of claim 8, wherein the second refresh signal and the third refresh signal are further based on a mode register setting.

11. The apparatus of claim 8, wherein an amount of time to refresh the set of memory banks responsive to the first refresh signal is shorter than the amount of time to refresh the set of memory banks responsive to the second refresh signal and the amount of time to refresh the set of memory banks responsive to the second refresh signal is shorter than the amount of time to refresh the set of memory banks responsive to the third refresh signal.

12. A method comprising:
receiving a first type of refresh command;
performing a refresh operation on a memory bank from a subset of memory bank groups from a plurality of memory bank groups responsive to the first type of refresh command.

13. The method of claim 12, further comprising performing the refresh operation on a memory bank from each of memory groups of the plurality of memory groups responsive to a second type of refresh command.

14. The method of claim 12, wherein the first type of refresh command is based on a command code and a first mode register setting and the second type of refresh command is based on the command code and a second mode register setting.

15. The method of claim 12, further comprising:
receiving a third type of refresh command; and
performing a refresh operation on all memory banks from all memory bank groups of the plurality of memory bank groups responsive to the third refresh command.

16. An apparatus comprising:
a memory array comprising a plurality of memory bank groups each comprising a plurality of memory banks; and
a refresh control circuit configured to:
perform a refresh operation on all memory banks from each of the memory bank groups of the plurality of memory bank groups responsive to a first refresh signal;
perform a refresh operation on a memory bank from each of the memory bank groups of the plurality of memory bank groups responsive to a second refresh signal; and
perform a refresh operation on a memory bank from a subset of memory bank groups of the plurality of memory bank groups responsive to a third refresh signal.

17. The apparatus of claim 16, further comprising a mode register including a mode register setting, wherein the second refresh signal is based on the mode register setting having a first value and the third refresh signal is based on the mode register setting having a second value.

18. The apparatus of claim 17, wherein the refresh control circuit comprises a refresh state control circuit configured to:
provide the first refresh signal responsive to a first refresh command;
provide the second refresh signal responsive to a second refresh command and a first mode register setting; and
provide the third refresh signal responsive to the second refresh command and a second mode register setting.

19. The apparatus of claim 18, wherein the mode register setting is set by a host.

20. The apparatus of claim 16, wherein an amount of time to refresh the set of memory banks responsive to the first refresh signal is shorter than the amount of time to refresh the set of memory banks responsive to the second refresh signal and the amount of time to refresh the set of memory banks responsive to the second refresh signal is shorter than the amount of time to refresh the set of memory banks responsive to the third refresh signal.
